(19) United States
(12) Patent Application Publication
(10) Pub. No.: US 2018/0041186 A1
(43) Pub. Date: Feb. 8, 2018

(54) SURFACE ACOUSTIC WAVE ELEMENTS WITH PROTECTIVE FILMS

(71) Applicant: SKYWORKS FILTER SOLUTIONS JAPAN CO., LTD., Kadoma-Shi (JP)

(72) Inventors: Toru Yamaji, Nagaokakyou-Shi (JP); Satoru Matsuda, Toyonaka-Shi (JP); Yoshiro Kabe, Kobe-Shi (JP)

(21) Appl. No.: 15/665,733

(22) Filed: Aug. 1, 2017

Related U.S. Application Data
(60) Provisional application No. 62/370,851, filed on Aug. 4, 2016.

(51) Int. Cl. H03H 9/02

(52) U.S. Cl. CPC H03H 9/02984; H03H 9/02897; H03H 9/02937; H03H 9/02929; H03H 9/02574

(57) ABSTRACT

A protection film for a surface acoustic wave element, the protection film being configured to prevent moisture absorption into a silicon dioxide film to improve the moisture resistance capability and configured to be unsusceptible to oxidation and stable such that the propagation characteristics of the surface acoustic wave are not adversely affected. The surface acoustic wave element includes a piezoelectric substrate having a top surface, an IDT electrode formed on the top surface of the piezoelectric substrate and including a plurality of electrode fingers configured to excite a surface acoustic wave, a first silicon dioxide film formed to cover the comb-shaped electrode on the top surface of the piezoelectric substrate, a silicon oxynitride film formed over and in contact with the first silicon dioxide film, and a second silicon dioxide film formed over and in contact with the silicon oxynitride film.

### CROSS-REFERENCE TO RELATED APPLICATIONS

This application claims the benefit under 35 U.S.C. §119(e) of co-pending U.S. Provisional Application No. 62/370,851 titled “SURFACE ACOUSTIC WAVE ELEMENTS” and filed on Aug. 4, 2016, which is herein incorporated by reference in its entirety for all purposes.

### BACKGROUND

Conventionally, a surface acoustic wave (SAW) element is protected by a technique for improving resistance against the absorption of moisture into a silicon dioxide (SiO₂) film. For example, International Publication No. WO2008/146449(A1) and Japanese Patent Publication No. 2011-254549(A) disclose techniques for forming a silicon oxynitride (SiON) film on a silicon dioxide film as a protection film to improve the moisture resistance capability of the surface acoustic wave element. Japanese Patent Publication No. 2011-061743(A) discloses a technique for forming silicon nitride (SiN) and silicon dioxide films as protection films.

FIGS. 1A and 1B illustrate a conventional surface acoustic wave element provided with a protection film configured as a silicon oxynitride film. FIG. 1A is a top view illustrating an electrode arrangement of the surface acoustic wave element, and FIG. 1B is a cross sectional view taken along line I-I (which extends in a propagation direction of a surface acoustic wave). A piezoelectric substrate 110 has a surface on which an interdigital transducer (IDT) electrode 111 and reflector electrodes 112, 113 are formed (referred to as a top surface 110a hereinafter). A silicon dioxide (SiO₂) film 121 is formed on the top surface 110a and a silicon oxynitride film 122 as a protection film is formed on and in contact with the silicon dioxide film 121.

### SUMMARY OF THE INVENTION

Aspects and embodiments relate to a surface acoustic wave element using a piezoelectric substrate and filter devices including the surface acoustic wave element.

In a conventional surface acoustic wave element such as that shown in FIGS. 1A and 1B, the silicon oxynitride film has a tendency to be easily oxidized. Accordingly, a part of the silicon oxynitride film may be converted to silicon dioxide such that the frequency characteristics of the surface acoustic wave element may be changed. Further, the silicon nitride can allow an acoustic velocity greater than that of the silicon dioxide and therefore, when a protection film having a certain film thickness is formed on the entire surface of the silicon dioxide film, the propagation characteristics of the surface acoustic wave may be adversely affected.

In view of the circumstances described above, aspects and embodiments provide a surface acoustic wave element having a protection film configured to prevent moisture absorption into a silicon dioxide film to improve the moisture resistance capability of the surface acoustic wave element and configured to be unsusceptible to oxidation and stable, such that the propagation characteristics of the surface acoustic wave are not adversely affected.

To solve the aforementioned problems, a surface acoustic wave element according to certain embodiments may include a piezoelectric substrate having a top surface, an interdigital transducer (IDT) electrode formed on the top surface of the piezoelectric substrate and including a plurality of electrode fingers configured to excite a surface acoustic wave, a first silicon dioxide film formed to cover the IDT electrode on the top surface of the piezoelectric substrate, a silicon oxynitride film formed in contact with the first silicon dioxide film, and a second silicon dioxide film formed in contact with the silicon oxynitride film.

In certain embodiments, the silicon oxynitride film may have a first film thickness and a second film thickness, the second film thickness corresponding to an area for at least one portion of the plurality of electrode fingers, the first film thickness corresponding to a remaining area of the area for the at least one portion, and the second film thickness being greater than the first film thickness.

In certain embodiments, the surface acoustic wave element may further include a silicon nitride film formed to be sandwiched between the first silicon dioxide film and the silicon oxynitride film. The silicon nitride film may correspond to an area for at least one portion of the plurality of electrode fingers.

Further, another example of a surface acoustic wave element according to certain embodiments may include a piezoelectric substrate having a top surface, an interdigital transducer (IDT) electrode formed on the top surface of the piezoelectric substrate and including a plurality of electrode fingers configured to excite a surface acoustic wave, a first silicon dioxide film formed to cover the IDT electrode on the top surface of the piezoelectric substrate, a silicon nitride film formed in contact with the first silicon dioxide film, a silicon oxynitride film formed in contact with the silicon nitride film, and a second silicon dioxide film formed in contact with the silicon oxynitride film.

The silicon nitride film may have a first film thickness and a second film thickness greater than the first film thickness, the second film thickness corresponding to an area for at least one portion of the plurality of electrode fingers and the first film thickness corresponding to a remaining area of the area for the at least one portion.

An acoustic velocity of the surface acoustic wave allowed to propagate by the silicon oxynitride film may be adjustable by a composition of nitrogen and oxygen existing in the silicon oxynitride film, and the piezoelectric substrate may be made of lithium niobate or lithium tantalate.

Still further, another example of a surface acoustic wave element according to certain embodiments may include a piezoelectric substrate having a top surface, an interdigital transducer (IDT) electrode formed on the top surface of the piezoelectric substrate and including a plurality of electrode fingers configured to excite a surface acoustic wave, a silicon dioxide film formed to cover the IDT electrode on the top surface of the piezoelectric substrate, a moisture absorption prevention film formed to cover the silicon dioxide film, and an oxidation prevention film covering the moisture absorption prevention film.

According to certain aspects of the present disclosure, a protection film can be provided to prevent moisture absorption into a silicon dioxide film of a surface acoustic wave element to improve the moisture resistance capability, such that the changes in the frequency characteristics due to the oxidation can be suppressed and the propagation characteristics of the surface acoustic wave are not adversely affected.

Still other aspects, embodiments, and advantages of these exemplary aspects and embodiments are discussed in detail below. Embodiments and examples disclosed herein may be combined with other embodiments and examples in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIGS. 1A and 1B show a structure of a conventional surface acoustic wave element;

FIGS. 2A and 2B show cross sectional views of a surface acoustic wave element according to aspects of the present disclosure;

FIG. 3 shows a cross sectional view of a first variation of the surface acoustic wave element in accordance with the present disclosure;

FIG. 4 shows a cross sectional view of a second variation of surface acoustic wave element in accordance with the present disclosure;

FIG. 5 shows a cross sectional view of a third variation of the surface acoustic wave element in accordance with the present disclosure;

FIG. 6 shows a cross sectional view of a comparative example of a surface acoustic wave element;

FIG. 7 is a block diagram of one example of a filter module that can include one or more surface acoustic wave elements according to aspects of the present disclosure;

FIG. 8 is a block diagram of one example of a front-end module that can include one or more filter modules according to aspects of the present disclosure; and

FIG. 9 is a block diagram of one example of a wireless device including the front-end module of FIG. 8.

### DETAILED DESCRIPTION

Examples of surface acoustic wave (SAW) elements in accordance with aspects of the present disclosure are now described in detail with reference to the accompanying drawings.

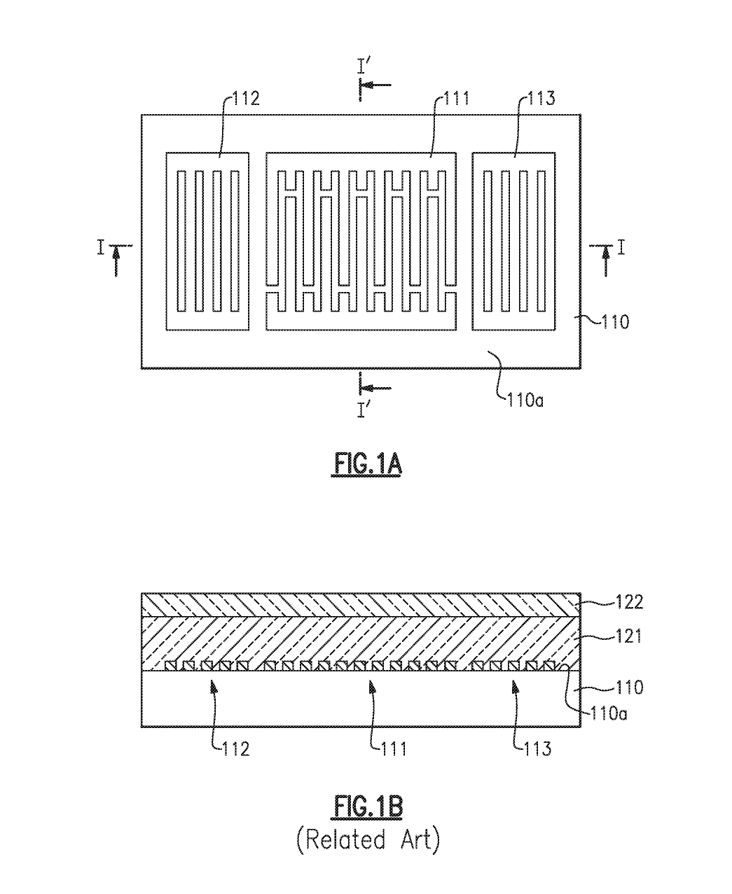

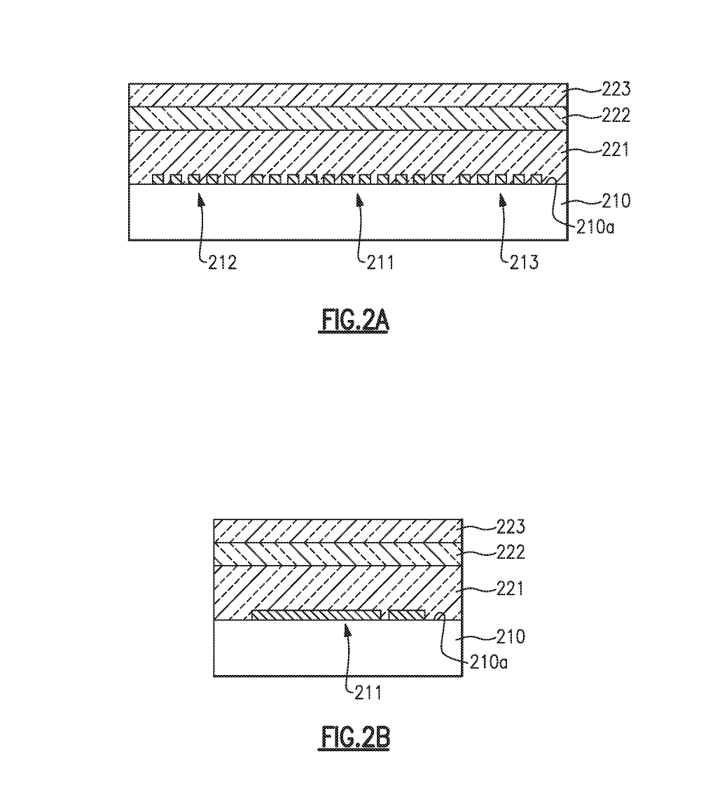

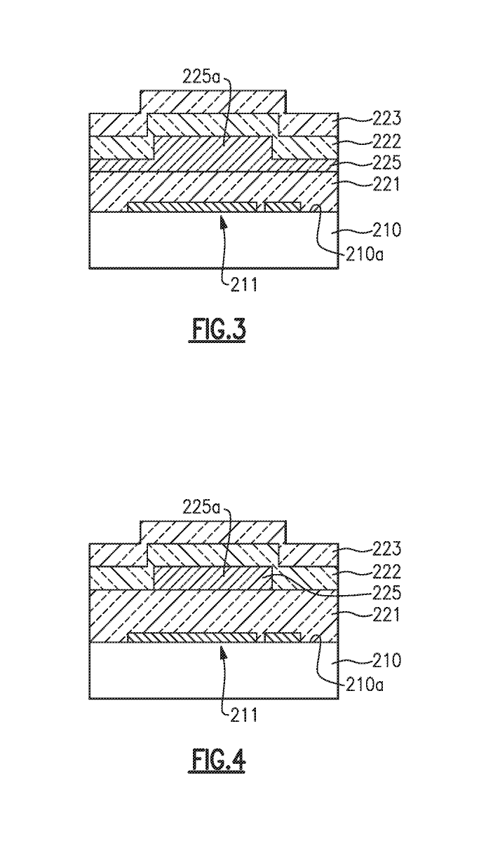

FIGS. 2A and 2B are cross sectional views of one example of a surface acoustic wave element according to an aspect of the present disclosure. FIG. 2A shows a cross sectional view of the surface acoustic wave element taken along line I-I illustrated in FIG. 1, in a propagation direction of the surface acoustic wave. FIG. 2B shows a cross sectional view of the surface acoustic wave element taken along line I′-I′ illustrated in FIG. 1A, in an extending direction of electrode fingers of the IDT electrode.

In the surface acoustic wave element, an interdigital transducer (IDT) electrode 211 is formed on a flat top surface 210a of a piezoelectric substrate 210 made of lithium niobate (LiNbO₃) to excite a surface acoustic wave. The IDT electrode 211 includes a pair of comb-shaped electrodes having electrode fingers that interdigitate with one another. Further, a first reflector electrode 212 and a second reflector electrode 213 are formed on either side of the IDT electrode 211 in a propagation direction of the surface acoustic wave to sandwich the IDT electrode 211 therebetween.

The piezoelectric substrate 210 may be made of lithium niobate with a 5° rotated Y-cut and X-propagation. The IDT electrode 211, the first reflector electrode 212 and the second reflector electrode 213 can be formed to contain aluminum as a main component and each to have a thickness of approximately 150 nanometers (nm). The surface acoustic wave element can be configured as a filter having a center frequency of approximately 2 GHz and may have a wavelength λ of approximately 2 micrometers (μm) for the surface acoustic wave.

A first silicon dioxide (SiO₂) film 221 having a certain film thickness is formed on the top surface 210a of the piezoelectric substrate 210 to cover the IDT electrode 211, the first reflector electrode 212 and the second reflector electrode 213. A silicon oxynitride (SiON) film 222 having a certain film thickness is formed in contact with the first silicon dioxide film 221, and a second silicon dioxide film 223 having a certain film thickness is formed in contact with the silicon oxynitride film 222.

The first silicon dioxide film 221 formed on the top surface 210a of the piezoelectric substrate 210 may suppress characteristic changes in the surface acoustic wave element, such as frequency changes of a surface acoustic wave propagating in the device caused by a thermal expansion or contraction due to changes in the ambient temperature of the piezoelectric substrate 210.

The silicon oxynitride film 222 formed in contact with the first silicon dioxide film 221 can block the permeation of moisture such that no moisture can reach the first silicon dioxide film 221 and thus moisture absorption into the first silicon dioxide film 221 can be prevented. The second silicon dioxide film 223 formed in contact with the silicon oxynitride film 222 can block the permeation of oxygen such that it does not reach the silicon oxynitride film 222 and oxidation of the silicon oxynitride film 222 can be prevented.

According to an aspect of the present disclosure, the double-layer structure formed by the silicon oxynitride film 222 and the second silicon dioxide film 223 can prevent both the moisture absorption into the first silicon dioxide film 221, and the oxidation of the silicon oxynitride film 222. In other words, the silicon oxynitride film 222 and the second silicon dioxide film 223 may function as a moisture absorption prevention film and an oxidation prevention film, respectively. Therefore, a deterioration of the propagation characteristics due to the moisture absorption into the first silicon dioxide film 221 can be prevented and the changes in the frequency characteristics due to the oxidation of the silicon oxynitride film 222 can also be prevented. As a result, it is possible to ensure the stable operation of the surface acoustic wave element and enhance the reliability thereof.

According to an aspect of the present disclosure, the composition of the silicon oxynitride constituting the silicon oxynitride film 222 need not be limited to SiON but can include SiOₓN₂₋ₓ (0<x<2). In this way, configuring the compositional ratio of nitrogen and oxygen of the silicon oxynitride film 222 can provide adjustability for an acoustic velocity of the silicon oxynitride film 222. Accordingly, it can be possible to properly control the propagation of the surface acoustic wave to improve the propagation characteristics of the surface acoustic wave element.

According to an aspect of the present disclosure, there is no need for a silicon nitride film to be formed with a substantially uniform film thickness on the entire surface of the first silicon dioxide film 221. Therefore, it can be possible to avoid forming silicon nitride over the entire surface and causing the surface acoustic wave to expand along the entire surface due to the greater acoustic velocity allowed by the silicon nitride, such that an adverse effect of the propagation characteristics can be prevented.

It is to be appreciated that, although the piezoelectric substrate 210 of the surface acoustic wave element described above employs lithium niobate, lithium tantalate (LiTaO₃) can also be used. Further, regardless of the dimensions for the respective portions as described above, other appropriate dimensions may be chosen. In addition, although only the IDT electrode 211, the first reflector electrode 212 and the second reflector electrode 213 are illustrated in the surface acoustic wave elements described herein, another IDT electrode, another reflector electrode, other circuitry, and the like can be included.

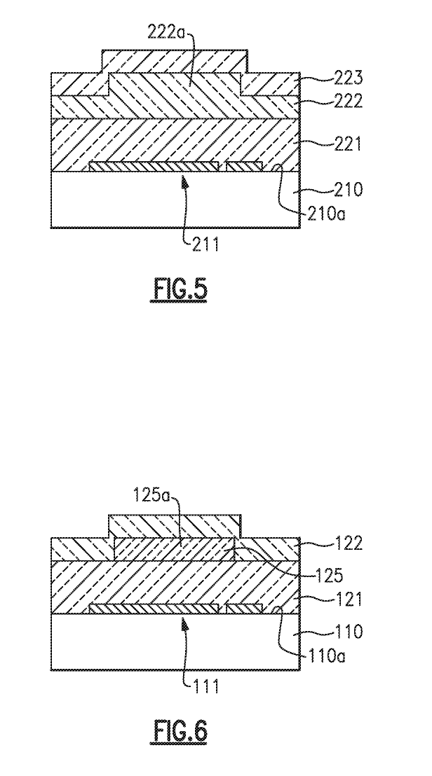

FIG. 3 is a cross sectional view representing a first variation of the surface acoustic wave element according to the present disclosure. Similar to FIG. 2B, FIG. 3 shows a cross sectional view of the surface acoustic wave element taken along line I′-I′ illustrated in FIG. 1A, in an extending direction of electrode fingers of the IDT electrode 211. The same applies to FIGS. 4 to 6 discussed below.

The first variation is different from the surface acoustic wave element shown in FIGS. 2A and 2B in that a silicon nitride (SiN) film 225 is formed between the first silicon dioxide film 221 and the silicon oxynitride film 222. Other than the presence of the silicon nitride film 225, the construction of the surface acoustic wave element illustrated in FIG. 3 is similar to the surface acoustic wave element described above with respect to FIGS. 2A and 2B.

In particular, according to this first variation, the silicon nitride film 225 is formed in contact with the first silicon dioxide film 221 having a certain film thickness formed to cover the IDT electrode 211 and the like on the top surface 210a of the piezoelectric substrate 210. The silicon nitride film 225 has a first film thickness, but a region 225a covering at least one portion of the IDT electrode 211 has a second film thickness greater than the first film thickness. The silicon oxynitride film 222 having a certain film thickness is formed in contact with the silicon nitride film 225. A second silicon dioxide film 223 is further formed to have a certain film thickness in contact with the silicon oxynitride film 222.

According to this first variation, the double-layer structure formed by the silicon oxynitride film 222 and the second silicon dioxide film 223 can prevent both moisture absorption into the first silicon dioxide film 221 and oxidation of the silicon oxynitride film 222. Therefore, a deterioration of the propagation characteristics due to the moisture absorption into the first silicon dioxide film 221 can be prevented and the changes in the frequency characteristics due to the oxidation of the silicon oxynitride film 222 can also be prevented.

Further, according to this first variation, the silicon nitride film 225 is formed to have a second film thickness greater than the first film thickness in a region 225a covering at least one portion of the IDT electrode 211. Because the silicon nitride has an acoustic velocity greater than that of the silicon dioxide, the surface acoustic wave energy can be intensively distributed around the region 225a covering at least one portion of the IDT electrode 211 and accordingly, the propagation characteristics can be improved. In addition, configuring the compositional ratio of nitrogen and oxygen of the silicon oxynitride film 222 can provide adjustability for an acoustic velocity of the silicon oxynitride film 222. Accordingly, it is possible to properly control the propagation of the surface acoustic wave to improve the propagation characteristics.

According to this first variation, disposing the silicon nitride film 225 in addition to the silicon oxynitride film 222 can additionally block the permeation of moisture. Therefore, it is possible to further improve the water resistance capability of the surface acoustic wave element.

FIG. 4 is a cross sectional view representing a second variation of the surface acoustic wave element according to the present disclosure. The second variation is structurally different from the surface acoustic wave element shown in FIGS. 2A and 2B in that a silicon nitride film 225 is formed to be sandwiched between the first silicon dioxide film 221 and the silicon oxynitride film 222. Further, the second variation is different from the first variation in that the silicon nitride film 225 covers only a portion of the first silicon dioxide film 221. However, other than the presence of the silicon nitride film 225 sandwiched between the first silicon dioxide film 221 and the silicon oxynitride film 222, the construction of the surface acoustic wave element illustrated in FIG. 4 is similar to the surface acoustic wave element described above with respect to FIGS. 2A and 2B.

In particular, according to this second variation, a silicon nitride film 225 having a certain film thickness is formed in a region 225a covering at least one portion of the IDT electrode 211. The silicon nitride film 225 is in contact with the first silicon dioxide film 221 that has a certain film thickness and is formed to cover the IDT electrode 211 and the like on the top surface 210a of the piezoelectric substrate 210. The silicon oxynitride film 222 having a certain film thickness is formed in contact with the first silicon dioxide film 221 to cover the silicon nitride film 225. A second silicon dioxide film 223 having a certain film thickness is further formed in contact with the silicon oxynitride film 222.

As with the surface acoustic wave elements described above with respect to FIGS. 2A and 2B, and FIG. 3, the double-layer structure formed by the silicon oxynitride film 222 and the second silicon dioxide film 223 can prevent both the moisture absorption into the first silicon dioxide film 221 and the oxidation of the silicon oxynitride film 222. Therefore, a deterioration of the propagation characteristics due to the moisture absorption into the first silicon dioxide film 221 can be prevented and the changes in the frequency characteristics due to the oxidation of the silicon oxynitride film 222 can also be prevented.

Further, according to this second variation, the silicon nitride film 225 is formed only in the region 225a covering at least one portion of the IDT electrode 211. Because the silicon nitride allows a greater acoustic velocity, the surface acoustic wave energy can be intensively distributed around the region 225a covering at least one portion of the IDT electrode 211 and accordingly the propagation characteristics can be improved. In addition, configuring the compositional ratio of nitrogen and oxygen of the silicon oxynitride film 222 can provide adjustability for an acoustic velocity of the silicon oxynitride film 222. Accordingly, it is possible to properly control the propagation of the surface acoustic wave to improve the propagation characteristics.

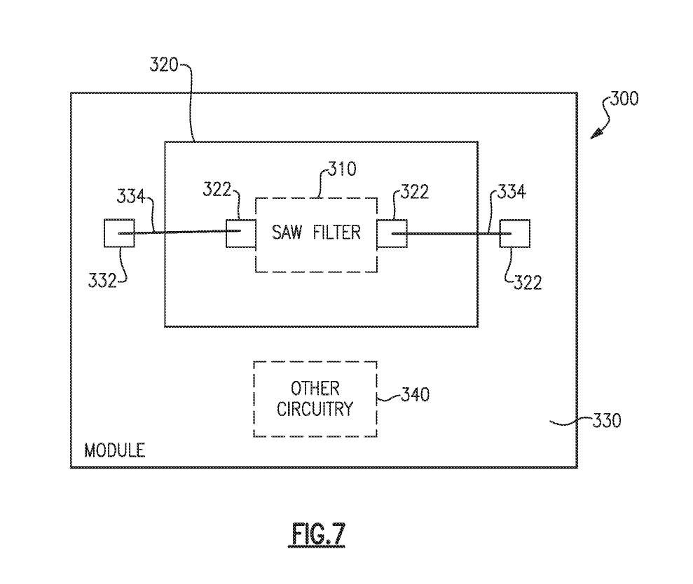

FIG. 5 is a cross sectional view representing a third variation of the surface acoustic wave element according to the present disclosure. The third variation is structurally different from the surface acoustic wave element shown in FIGS. 2A and 2B in that a silicon oxynitride film 222 generally having a first film thickness also has a second film thickness greater than the first film thickness in a region 222a covering at least one portion of the IDT electrode 211. However, other than the variation in the thickness of silicon oxynitride film 222, the surface acoustic wave element illustrated in FIG. 5 is similar to the surface acoustic wave element described above with respect to FIGS. 2A and 2B.

In particular, according to the third variation, the silicon oxynitride film 222 is formed in contact with the first silicon dioxide film 221 having a certain film thickness formed to cover the IDT electrode 211 and the like on the top surface 210a of the piezoelectric substrate 210. Although the silicon oxynitride film 222 generally has a first film thickness, the silicon oxynitride film 222 also has a second film thickness greater than the first film thickness in the region 222a covering at least one portion of the IDT electrode 211. A second silicon dioxide film 223 is further formed to have a certain film thickness in contact with the silicon oxynitride film 222.

As with the previously described surface acoustic wave elements, the double-layer structure formed by the silicon oxynitride film 222 and the second silicon dioxide film 223 can prevent both the moisture absorption into the first silicon dioxide film 221 and the oxidation of the silicon oxynitride film 222. Therefore, a deterioration of the propagation characteristics due to the moisture absorption into the first silicon dioxide film 221 can be prevented and the changes in the frequency characteristics due to the oxidation of the silicon oxynitride film 222 can also be prevented.

Further, according to this third variation, the silicon oxynitride film 222 is formed to have a second film thickness greater than the first film thickness in the region 222a covering at least one portion of the IDT electrode 211. Here, the silicon oxynitride film 222 may have the acoustic velocity adjusted to a desired value by configuring the compositional ratio of nitrogen and oxygen contained therein. Therefore, it can be possible to control the energy distribution of the surface acoustic wave, such that the propagation characteristics can be improved.

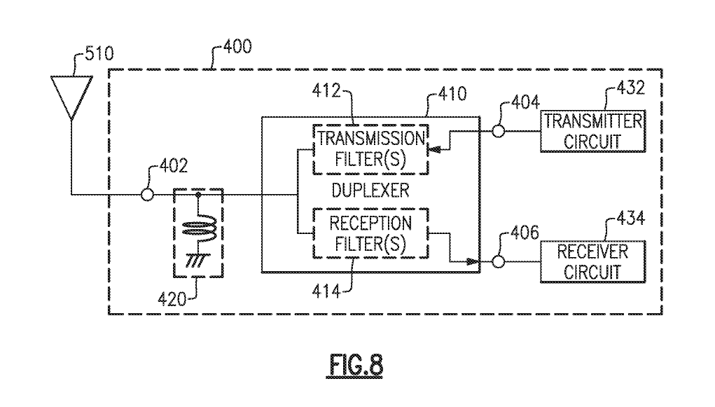

FIG. 6 is a cross sectional view representing an example of a surface acoustic wave element as a comparative example. According to the comparative example, a silicon dioxide film 121 is formed to have a certain film thickness to cover an IDT electrode 111 and the like on the top surface 110a of a piezoelectric substrate 110. The silicon nitride film 125 having a certain film thickness is formed in contact with the silicon dioxide film 121 only in a region 125a covering at least one portion of the IDT electrode 111. A silicon oxynitride film 122 having a certain film thickness is further formed in contact with the silicon dioxide film 121 to cover the silicon nitride film 125.

According to the comparative example, the silicon nitride film 125 is formed only in the region covering at least one portion of the IDT electrode 111 around which the surface acoustic wave energy can be intensively distributed, such that the propagation characteristics can be improved. Further, the silicon oxynitride film 122 can prevent the moisture absorption into the silicon dioxide film 121.

In the surface acoustic wave elements previously described with respect to FIGS. 2-5, the second silicon dioxide film 223 is provided as an oxidation prevention film to prevent the oxidation of the silicon oxynitride film 222 corresponding to the silicon oxynitride film 122, such that changes in the frequency characteristics can be avoided. In contrast, in the comparative example, a surface of the silicon oxynitride film 122 may be oxidized and converted to silicon dioxide, and therefore the frequency characteristics of the surface acoustic wave element may be changed.

As discussed above, embodiments of the surface acoustic wave elements can be configured as or used in filters, for example. In turn, a surface acoustic wave (SAW) filter using one or more surface acoustic wave elements may be incorporated into and packaged as a module that may ultimately be used in an electronic device, such as a wireless communications device, for example. FIG. 7 is a block diagram illustrating one example of a module 300 including a SAW filter 310. The SAW filter 310 may be implemented on one or more die(s) 320 including one or more connection pads 322. For example, the SAW filter 310 may include a connection pad 322 that corresponds to an input contact for the SAW filter and another connection pad 322 that corresponds to an output contact for the SAW filter. The packaged module 300 includes a packaging substrate 330 that is configured to receive a plurality of components, including the die 320. A plurality of connection pads 332 can be disposed on the packaging substrate 330, and the various connection pads 322 of the SAW filter die 320 can be connected to the connection pads 332 on the packaging substrate 330 via electrical connectors 334, which can be solder bumps or wirebonds, for example, to allow for passing of various signals to and from the SAW filter 310. The module 300 may optionally further include other circuitry die 340, such as, for example one or more additional filter(s), amplifiers, pre-filters, modulators, demodulators, down converters, and the like, as would be known to one of skill in the art of semiconductor fabrication in view of the disclosure herein. In some embodiments, the module 300 can also include one or more packaging structures to, for example, provide protection and facilitate easier handling of the module 300. Such a packaging structure can include an overmold formed over the packaging substrate 330 and dimensioned to substantially encapsulate the various circuits and components thereon.

Various examples and embodiments of the SAW filter 310 can be used in a wide variety of electronic devices. For example, the SAW filter 310 can be used in an antenna duplexer, which itself can be incorporated into a variety of electronic devices, such as RF front-end modules and communication devices.

Referring to FIG. 8, there is illustrated a block diagram of one example of a front-end module 400, which may be used in an electronic device such as a wireless communications device (e.g., a mobile phone) for example. The front-end module 400 includes an antenna duplexer 410 having a common node 402, an input node 404, and an output node 406. An antenna 510 is connected to the common node 402.

The antenna duplexer 410 may include one or more transmission filters 412 connected between the input node 404 and the common node 402, and one or more reception filters 414 connected between the common node 402 and the output node 406. The passband(s) of the transmission filter(s) are different from the passband(s) of the reception filters. Examples of the SAW filter 310 can be used to form the transmission filter(s) 412 and/or the reception filter(s) 414. An inductor or other matching component 420 may be connected at the common node 402.

The front-end module 400 further includes a transmitter circuit 432 connected to the input node 404 of the duplexer 410 and a receiver circuit 434 connected to the output node 406 of the duplexer 410. The transmitter circuit 432 can generate signals for transmission via the antenna 510, and the receiver circuit 434 can receive and process signals received via the antenna 510. In some embodiments, the receiver and transmitter circuits are implemented as separate components, as shown in FIG. 8, however in other embodiments these components may be integrated into a common transceiver circuit or module. As will be appreciated by those skilled in the art, the front-end module 400 may include other components that are not illustrated in FIG. 8 including, but not limited to, switches, electromagnetic couplers, amplifiers, processors, and the like.

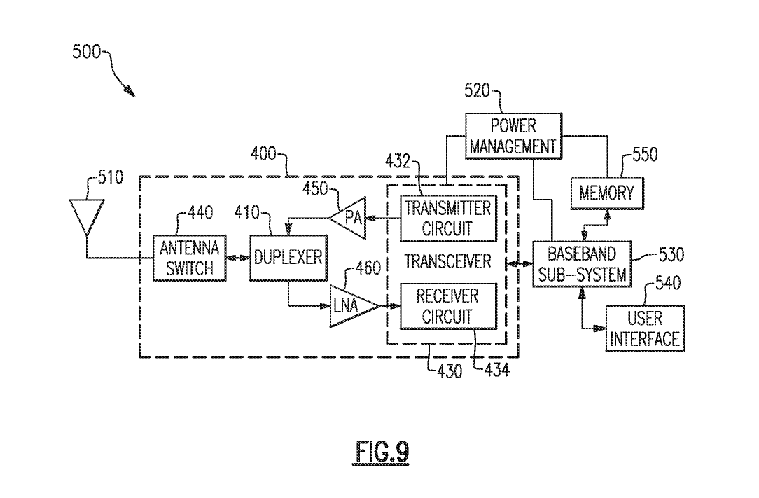

FIG. 9 is a block diagram of one example of a wireless device 500 including the antenna duplexer 410 shown in FIG. 8. The wireless device 500 can be a cellular phone, smart phone, tablet, modem, communication network or any other portable or non-portable device configured for voice or data communication. The wireless device 500 can receive and transmit signals from the antenna 510. The wireless device includes an embodiment of a front-end module 400 similar to that discussed above with reference to FIG. 8. The front-end module 400 includes the duplexer 410, as discussed above. In the example shown in FIG. 9 the front-end module 400 further includes an antenna switch 440, which can be configured to switch between different frequency bands or modes, such as transmit and receive modes, for example. In the example illustrated in FIG. 9, the antenna switch 440 is positioned between the duplexer 410 and the antenna 510; however, in other examples the duplexer 410 can be positioned between the antenna switch 440 and the antenna 510. In other examples the antenna switch 440 and the duplexer 410 can be integrated into a single component.

The front-end module 400 includes a transceiver 430 that is configured to generate signals for transmission or to process received signals. The transceiver 430 can include the transmitter circuit 432, which can be connected to the input node 404 of the duplexer 410, and the receiver circuit 434, which can be connected to the output node 406 of the duplexer 410, as shown in the example of FIG. 8.

Signals generated for transmission by the transmitter circuit 432 are received by a power amplifier (PA) module 450, which amplifies the generated signals from the transceiver 430. The power amplifier module 450 can include one or more power amplifiers. The power amplifier module 450 can be used to amplify a wide variety of RF or other frequency-band transmission signals. For example, the power amplifier module 450 can receive an enable signal that can be used to pulse the output of the power amplifier to aid in transmitting a wireless local area network (WLAN) signal or any other suitable pulsed signal. The power amplifier module 450 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 450 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 9, the front-end module 400 may further include a low noise amplifier module 460, which amplifies received signals from the antenna 510 and provides the amplified signals to the receiver circuit 434 of the transceiver 430.

The wireless device 500 of FIG. 9 further includes a power management sub-system 520 that is connected to the transceiver 430 and manages the power for the operation of the wireless device 500. The power management system 520 can also control the operation of a baseband sub-system 530 and various other components of the wireless device 500. The power management system 520 can include, or can be connected to, a battery (not shown) that supplies power for the various components of the wireless device 500. The power management system 520 can further include one or more processors or controllers that can control the transmission of signals, for example. In one embodiment, the baseband sub-system 530 is connected to a user interface 540 to facilitate various input and output of voice and/or data provided to and received from the user. The baseband sub-system 530 can also be connected to memory 550 that is configured to store data and/or instructions to facilitate the operation of the wireless device, and/or to provide storage of information for the user.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. It is to be appreciated that embodiments of the methods and apparatuses discussed herein are not limited in application to the details of construction and the arrangement of components set forth in the description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. Any references to front and back, left and right, top and bottom, upper and lower, and vertical and horizontal are intended for convenience of description, not to limit the present systems and methods or their components to any one positional or spatial orientation Accordingly, the foregoing description and drawings are by way of example only, and the scope of the invention should be determined from proper construction of the appended claims, and their equivalents.

What is claimed is:

1. A surface acoustic wave element comprising:
a piezoelectric substrate having a top surface;
an interdigital transducer (IDT) electrode formed on the top surface of the piezoelectric substrate and including a plurality of electrode fingers configured to excite a surface acoustic wave;
a first silicon dioxide film formed to cover the IDT electrode on the top surface of the piezoelectric substrate;
a silicon oxynitride film formed over and in contact with the first silicon dioxide film; and
a second silicon dioxide film formed over and in contact with the silicon oxynitride film.

2. The surface acoustic wave element of claim 1 wherein the silicon oxynitride film has a first film thickness in a first region and a second film thickness in a second region, the second region corresponding to an area for at least a portion of the plurality of electrode fingers, and the second film thickness being greater than the first film thickness.

3. The surface acoustic wave element of claim 1 further comprising a silicon nitride film formed sandwiched between the first silicon dioxide film and the silicon oxynitride film.

4. The surface acoustic wave element of claim 3 wherein the silicon nitride film corresponds to an area of at least a portion of the plurality of electrode fingers.

5. The surface acoustic wave element of claim 3 wherein the silicon nitride film has a first film thickness in a first region and a second film thickness in a second region, the second region corresponding to an area for at least a portion of the plurality of electrode fingers, and the second film thickness being greater than the first film thickness.

6. The surface acoustic wave element of claim 1 further comprising first and second reflector electrodes formed on the top surface of the piezoelectric substrate on either side of the IDT electrode such that the IDT electrode is disposed between the first and second reflector electrodes in a direction of propagation of the surface acoustic wave.

7. The surface acoustic wave element of claim 1 wherein an acoustic velocity of the surface acoustic is adjustable by controlling a composition of nitrogen and oxygen in the silicon oxynitride film.

8. The surface acoustic wave element of claim 1 wherein the piezoelectric substrate is made of lithium niobate or lithium tantalate.

9. A surface acoustic wave element comprising:
a piezoelectric substrate having a top surface;
an interdigital transducer (IDT) electrode formed on the top surface of the piezoelectric substrate and including a plurality of electrode fingers configured to excite a surface acoustic wave;
a first silicon dioxide film formed to cover the IDT electrode on the top surface of the piezoelectric substrate;
a silicon nitride film formed over and in contact with the first silicon dioxide film;
a silicon oxynitride film formed over and in contact with the silicon nitride film, the silicon nitride film being disposed between the first silicon dioxide film and the silicon oxynitride film; and
a second silicon dioxide film formed over and in contact with the silicon oxynitride film, the silicon oxynitride film being disposed between the silicon nitride film and the second silicon dioxide film.

10. The surface acoustic wave element of claim 9 wherein the silicon nitride film has a first film thickness in a first region and a second film thickness greater than the first film thickness in a second region, the second region corresponding to an area for at least a portion of the plurality of electrode fingers.

11. The surface acoustic wave element of claim 9 wherein an acoustic velocity of the surface acoustic wave is adjustable by controlling a composition of nitrogen and oxygen in the silicon oxynitride film.

12. The surface acoustic wave element of claim 9 wherein the piezoelectric substrate is made of lithium niobate or lithium tantalate.

13. A surface acoustic wave element comprising:
a piezoelectric substrate having a top surface;
an interdigital transducer (IDT) electrode formed on the top surface of the piezoelectric substrate and including a plurality of electrode fingers configured to excite a surface acoustic wave;
a silicon dioxide film formed to cover the IDT electrode on the top surface of the piezoelectric substrate;
a moisture absorption prevention film formed to cover the silicon dioxide film; and
an oxidation prevention film formed to cover the moisture absorption prevention film.

14. The surface acoustic wave element of claim 13 further comprising first and second reflector electrodes formed on the top surface of the piezoelectric substrate on either side of the IDT electrode such that the IDT electrode is disposed between the first and second reflector electrodes in a propagation direction of the surface acoustic wave.

15. The surface acoustic wave element of claim 14 wherein the moisture absorption prevention film is a silicon oxynitride film.

16. The surface acoustic wave element of claim 15 wherein the oxidation prevention film is made of silicon dioxide.

17. The surface acoustic wave element of claim 16 further comprising a silicon nitride film disposed between the silicon dioxide film and the moisture absorption prevention film.

18. The surface acoustic wave element of claim 16 wherein the moisture absorption prevention film has a first film thickness in a first region of the surface acoustic wave element and a second film thickness in a second region of the surface acoustic wave element, the second region corresponding to an area of at least a portion of the plurality of electrode fingers, and the second film thickness being greater than the first film thickness.

19. The surface acoustic wave element of claim 14 wherein the moisture absorption prevention film has a chemical composition of SiOₓN₂₋ₓ, where 0<x<2.

20. The surface acoustic wave element of claim 13 wherein the piezoelectric substrate is made of lithium niobate or lithium tantalate.
